(19) United States
(12) Patent Application Publication
(10) Pub. No.: US 2007/0188055 A1
(43) Pub. Date: Aug. 16, 2007

(54) Piezoelectric resonator element and piezoelectric device

(75) Inventor: Takuo KUWAHARA, Tokyo (JP)

Correspondence Address: HARNESS, DICKEY & PIERCE, P.L.C., P.O. BOX 828, BLOOMFIELD HILLS, MI, 48303, US

(73) Assignee: EPSON TOYOCOM CORPORATION, Tokyo (JP)

(21) Appl. No.: 11/627,117

(22) Filed: Jan. 25, 2007

(30) Foreign Application Priority Data
Jan. 27, 2006 (JP) 2006-019525

(51) Int. Cl. H03H 9/21

(52) U.S. Cl. 310/370

(57) ABSTRACT

A tuning fork-type piezoelectric resonator element includes a base section made of a piezoelectric material, and at least a pair of resonating arms formed integrally with the base section that extend parallel to each other from the base section. Based on a displacement vortex generated by flexural vibration of the pair of resonating arms near the base end of each resonating arm of the base section and on a virtual center line that passes through a center width of each resonating arm, a groove or slit is provided along a line tangent to a periphery of the displacement vortex.

### FIELD

The present teachings relate to a tuning fork-shaped piezoelectric resonator element, and a piezoelectric device in which the piezoelectric resonator element is housed in a package or case.

### BACKGROUND

Piezoelectric devices such as piezoelectric resonators or piezoelectric oscillators in which a piezoelectric resonator element is housed in a package or the like are widely used for small information equipment such as a hard disk drive (HDD), mobile computer or chip card, a mobile communication device such as a mobile telephone, car telephone or paging system, and a measurement instrument such as a gyro sensor.

A piezoelectric resonator element used in such a piezoelectric device is described in JP-UM-4-2002-76806.

The piezoelectric resonator element described in JP-UM-4-2002-76806 is formed, for example, of a single crystal of quartz, and is a tuning-fork type resonator element including a wide base section and two resonating arms extending from the base section parallel to each other in the same direction.

Further, in the piezoelectric resonator element described in JP-UM-4-2002-76806, a long groove extending in the longitudinal direction is formed on each of the front and back surfaces of each of the resonating arms. An excitation electrode that serves as the drive electrode is formed in the long groove.

By applying a drive voltage from the outside to the excitation electrode, an electric field is generated in the resonating arms efficiently, and thus the resonating arms flexurally vibrate so that the distal ends thereof move towards and away from each other. Next, a resonance frequency based on the flexural vibration is taken out and used for a reference signal, such as a clock signal, for control.

Recently, however there has arisen a need for miniaturizing piezoelectric devices to adapt the device to a product in which the device is mounted. As a result tuning-fork type resonator elements mounted in the piezoelectric devices are getting considerably smaller to the extent where the full length thereof is approximately 2 mm or less.

In addition, in a miniaturized tuning-fork type piezoelectric resonator element, vibration leakage in flexural vibration of the resonating arms may be transmitted to the base section. Accordingly, the crystal impedance (CI) value increases and temperature characteristics are deteriorated in accordance with increase in unwanted mode.

### SUMMARY

The present teachings provide a piezoelectric resonator that is element capable of suppressing unwanted modes, even if it is miniaturized, without extremely increasing the CI value to prevent the temperature characteristics from being deteriorated. The present teachings also provide a piezoelectric device using the resonator element.

A tuning fork-type piezoelectric resonator element according to a first aspect of the present teachings includes a base section made of a piezoelectric material, and at least a pair of resonating arms which are formed integrally with the base section and which extend from the base section parallel to each other. Based on a displacement vortex which is generated by flexural vibration of the pair of resonating arms in the vicinity of a base end of each of the resonating arms near the base section, and on a virtual center line that passes through a center width of each resonating arm, a groove or slit is provided along a tangent line to a periphery of the displacement vortex, which is substantially circular.

According to this configuration, the pair of resonating arms flexurally vibrate so that the distal ends thereof move toward and away from each other. Therefore, the displacement amount at the distal ends of resonating arms is the greatest, and the displacement amount decreases as the base section which serves as the base end of the resonating arms is approached. Based on FEM analysis (shown in a vector diagram that simulates of resonating displacement when each of the resonating arms is flexurally vibrating), a displacement vortex (which may also be referred to as the center of the displacement of flexural vibration) is observed in the vicinity of the base end of each resonating arm, and on the virtual center line that passes through the center width of each resonating arm.

Provision of a so called fragile section formed by a groove or slit along a tangent line to a periphery of the displacement vortex, which is substantially circular, makes deformation or displacement on the basis of the displacement vortex easier. According to such configuration, vibration leakage from the resonating arm is eliminated at the groove or slit position of the base section, and the vibration leakage is prevented from being transmitted to a portion of the resonator element that is joined to the package. As a result, increases in the CI value and unwanted modes are difficult to occur and deterioration of temperature characteristics can be prevented.

Note that the term “groove or slit” as a configuration for achieving the operational effects as described above is used as an expression for facilitating understanding of the “fragile section”. Therefore, a case where a “fragile section” which cannot be generally referred to as “groove or slit” is formed is also contemplated by the present teachings.

According to a second aspect of the piezoelectric resonator element, a groove or slit may be provided along a tangent line to a circle concentric with the periphery of the displacement vortex, in place of the groove or slit along the tangent line to the periphery of the displacement vortex, or in addition to the groove or slit.

According to this configuration, provision of the groove or slit along the circle concentric with the displacement vortex enables forming a fragile section in accordance with the stress corresponding to the displacement, thereby making displacement along the fragile section easier. Accordingly, the configuration may achieve an operational effect almost equal to that of the first aspect of the invention.

In the piezoelectric resonator element, a groove or slit may be provided along a tangent line to a circle which is created by moving a circle corresponding to the periphery of the displacement vortex in a direction in which the virtual center line extends or along a tangent line to a circle concentric with the circle that has been transferred, in place of the groove or slit along the tangent line to the periphery of the displacement vortex, or in addition to the groove or slit.

According to this configuration, formation of a groove or slit along the tangent line or a groove or slit along a tangent line to the circle concentric therewith may achieve an operational effect almost equal to that of the first or second aspect of the invention.

In the piezoelectric resonator element, the groove or slit may be provided parallel to a direction that diagonally intersects the direction in which the resonating arm is extends.

According to the configuration, the displacement vortex is substantially circular. Accordingly, even if the groove or slit that serves as the fragile section is provided parallel to the direction that diagonally intersects the direction in which the resonating arm extend, the groove or slit is along the direction in which the displacement vortex is formed. As a result, an operational effect almost equal to the first or second aspect of the inventions may be achieved.

In the piezoelectric resonator element, the groove or slit may be provided parallel to the direction perpendicular to the direction in which the resonating arm extends.

According to the configuration, the displacement vortex is substantially circular. Accordingly, even if the groove or slit that serves as the fragile section is provided parallel to the direction perpendicular to the direction in which the resonating arm extends, the groove or slit is along the direction in which the displacement vortex is formed. As a result, an operational effect almost equal to the first or second aspect of the inventions may be achieved.

In the piezoelectric resonator element, the groove or slit may be provided parallel to the direction in which the resonating arm extends.

According to the configuration, the displacement vortex is substantially circular. Accordingly, even if the groove or slit that serves as the fragile section is provided parallel to the direction in which the resonating arm extends, the groove or slit is along the direction in which the displacement vortex is formed. As a result, an operational effect almost equal to the first or second aspect of the inventions may be achieved.

In the piezoelectric resonator element, the groove or slit may be provided in a curved shape along the tangent line direction and along the periphery of the displacement vortex or the circle concentric with the displacement vortex.

According to the configuration, the displacement vortex is substantially circular. Accordingly, even if the groove or slit that serves as the fragile section is provided in a curved shape along the tangent line direction and along the periphery of the displacement vortex or the circle concentric with the displacement vortex, the groove or slit is along the direction in which the displacement vortex is formed. As a result, an operational effect almost equal to the first or second aspect of the inventions may be achieved.

In the piezoelectric resonator element, each of the resonating arms may include a long groove that extends in the longitudinal direction and an excitation electrode formed in the long groove.

According to the configuration, electrolysis efficiency can be increased when driving the resonating arms by applying a drive voltage thereto.

A piezoelectric device according to a third aspect of the invention houses a piezoelectric resonator element in a housing container. The piezoelectric resonator element may include a base section made of a piezoelectric material, and at least a pair of resonating arms formed integrally with the base section that extend parallel to each other from the base section. Based on a displacement vortex which is generated by flexural vibration of the pair of resonating arms in the vicinity of a base end of each of the resonating arms of the base section and on a virtual center line that passes through a width center of each resonating arm, a groove or slit may be provided along a tangent line to a periphery of the displacement vortex, which is substantially circular.

### DRAWINGS

The drawings described herein are for illustration purposes only and are not intended to limit the scope of the present disclosure in any way.

FIG. 1 is a schematic plan view of a piezoelectric device according to the present teachings;

FIG. 2 is a schematic cross-sectional view cut alone Line A-A of the piezoelectric device in FIG. 1;

FIG. 3 is a schematic plan view of a piezoelectric resonator element which may be used in the piezoelectric device in FIG. 1;

FIG. 4 is an end elevation view cut along Line B-B of the piezoelectric resonator element in FIG. 3;

FIG. 5 is a vector diagram showing a simulation of resonating displacement in the vicinity of the base section when the resonating arms are flexurally vibrating in a reference example of a piezoelectric resonator element which is not part of the present teachings;

FIG. 6 is a schematic plan view of a piezoelectric resonator element according to the present teachings;

FIG. 7 is a schematic plan view of another piezoelectric resonator element according to the present teachings;

FIG. 8 is a schematic plan view of yet another piezoelectric resonator element according to the present teachings;

FIG. 9 is a schematic plan view of yet another piezoelectric resonator element according to the present teachings

FIG. 10 is a schematic plan view of yet another piezoelectric resonator element according to the present teachings

### DETAILED DESCRIPTION

The following description is merely exemplary in nature and is not intended to limit the present disclosure, application, or uses.

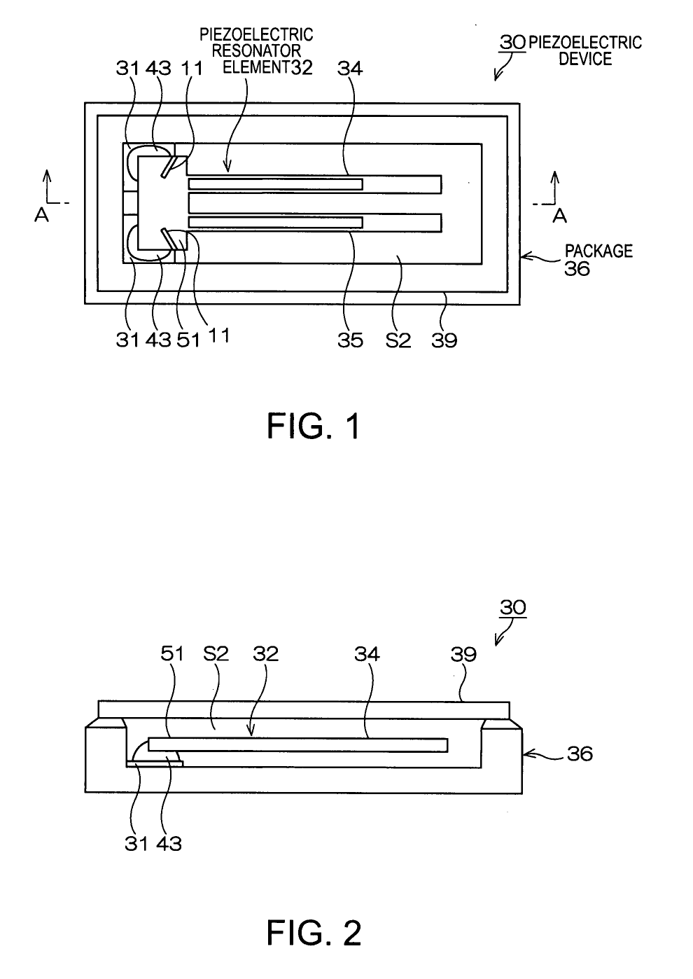

FIG. 1 and FIG. 2 show a piezoelectric device according to the present teachings. FIG. 1 is a plan view thereof and FIG. 2 is a schematic cross-sectional view cut along Line A-A in FIG. 1.

Referring to the drawings, of a piezoelectric device 30 configured from a quarts crystal resonator is shown. The piezoelectric device 30 houses a piezoelectric resonator element 32 in a package 36 which serves as a container. The package 36 may be formed by first laminating a plurality of substrates which serve, for example, as insulating materials and are created by forming a ceramic green sheet made of aluminum oxide, and then sintering the substrates. A predetermined hole may be created on the inner side of each of the plurality of substrates, and thereby a predetermined inner space S2 may be created on the inner side of the substrates when the substrates are laminated. The inner space S2 may be a housing space for housing the piezoelectric resonator element 32.

The piezoelectric resonator element 32 may be mounted on the inner side of the packages 36, and the package 36 may be sealed with a cover 39 in air tight manner. The cover 39 herein may be formed of a material selected from ceramic, metal, glass, and the like.

For example, if the cover 39 is made of metal, it generally has an advantage that it has a higher strength than other materials. A material with an expansion coefficient that is similar to that of the package 36 may be suitable for the material of the cover 39. For example, Kovar may be used.

Alternatively, the cover 39 may be made of an optically-transparent material such as glass to enable adjustment of a frequency after the cover 39 is sealed. For example, a board body made of borosilicate glass or the like may be used.

Referring to FIG. 1 showing the inner space S2 of the package 36, electrode sections 31 formed of nickel-plated and gold-plated tungsten metallized layers may be provided on laminated substrates that are exposed to the inner space S2 and that constitute the inside bottom section thereof. The electrode sections 31 may be connected to the exterior of the package 36 and supply a drive voltage. Conductive adhesives 43 may be applied on top of the electrode sections 31, and a base section 51 of the piezoelectric resonator element 32 is mounted on the conductive adhesives 43. Subsequently, the conductive adhesives 43 are cured. A synthetic resin agent that incorporates conductive particles, such as silver particles, may be used as the conductive adhesives 43. A silicone-based, epoxy-based, or polyimide-based conductive adhesive may also be used as the conductive adhesive 43.

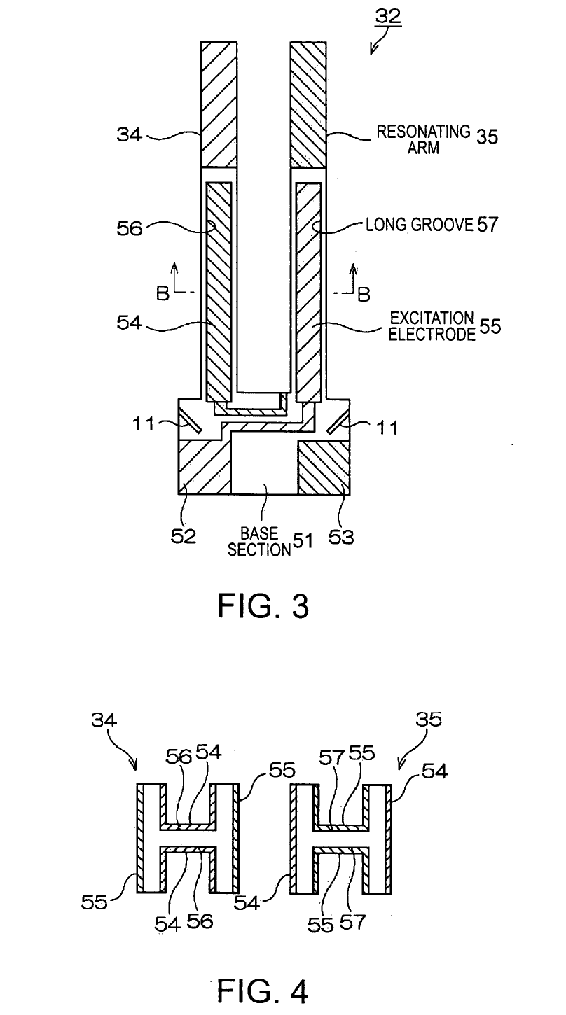

The piezoelectric resonator element 32 is formed by etching, for example, a quartz crystal as the piezoelectric material. The piezoelectric resonator element 32 is particularly configured as shown in the schematic plan view of FIG. 3, and an end elevation view cut along Line B-B of FIG. 3 as shown in FIG. 4, to achieve required performance with a reduced size.

A so-called tuning-fork type piezoelectric resonator element which has a tuning-fork shape may be used as the piezoelectric resonator element 32. The piezoelectric resonator element 32 may include the base section 51 fixed to the package 36 and a pair of resonating arms 34, 35 that are branched from the base section 51 and extend parallel to each other.

The piezoelectric resonator element 32 is very small as a whole. Referring to FIG. 3, the piezoelectric resonator element 32 may be, for example, an extremely small piezoelectric resonator element of approximately 1,300 μm in length, approximately 1,040 μm in arm length, and approximately 40 to 55 μm in arm width.

Referring to FIG. 3 and FIG. 4, long and bottomed grooves 56, 57 that extend in the longitudinal direction of the resonating arms 34, 35 are respectively formed in the piezoelectric resonator element 32. As shown in FIG. 4, the long grooves 56, 57 may be formed on both top and bottom surfaces of the resonating arms 34, 35.

Further, referring to FIG. 3, extraction electrodes 52, 53 may be formed in both ends in the width direction of the end portion (the bottom end portion in FIG. 3) of the base section 51. The extraction electrodes 52, 53 may also be formed on the bottom surface (not shown) of the base section 51 in a similar manner.

As described above, the extraction electrodes 52, 53 may be connected to the electrode sections 31 with conductive adhesives 43 as shown in FIG. 1. Further, the extraction electrodes 52, 53 may be integrally connected to excitation electrodes 54, 55 that are provided in the long grooves 56, 57 of the resonating arms 34, 35. In addition, as shown in FIG. 4, the excitation electrodes 54, 55 may also be formed on side surfaces of the resonating arms 34, 35. The excitation electrodes 54, 55 in the long grooves 56, 57 may have opposite polarities

In addition, as shown in FIG. 1 and FIG. 3, a pair of slits 11 that serve as fragile sections may be formed at the base section 51 of the piezoelectric resonator element 32. The slits 11 may be used to make deformation or displacement on the basis of displacement vortexes, which are to be described later, easier. The displacement vortexes are respectively created in an area of the base ends of the resonating arms 34, 35 in the base section 51 and on virtual center lines that pass through the center widths of the resonating arms 34, 35. The configuration thereof will be hereafter described in detail.

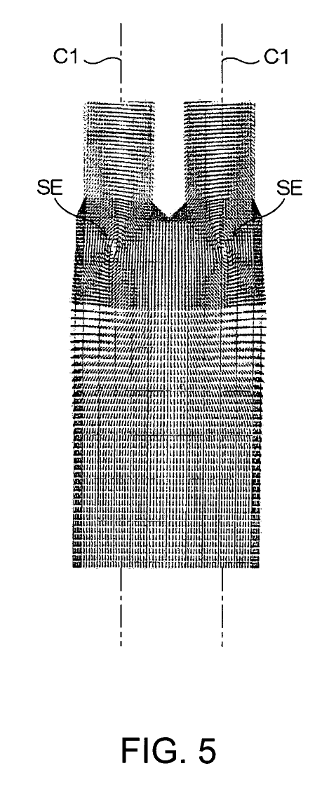

FIG. 5 is a vector diagram showing an FEM analyzed-simulation on resonating displacement of the resonating arms of a common tuning-fork type resonator element in a state where the resonating arms are flexurally vibrating in which distal ends thereof move towards and away from each other.

Referring to the drawing, CI denote virtual center lines that pass through middle points of the width dimension of the respective resonating arms. A pair of displacement vortexes SE which may also be referred to as centers of displacement of the flexural vibration, are observed in the vicinity of the base ends of the respective resonating arms of the base section and on the virtual center lines CI. The displacement vortexes SE are symmetric with each other with respect to the center width of the base section.

According to the present teachings, for example, a (bottomed) groove and/or slit (penetrating the material of the base section) may be formed as fragile sections in the base section on the basis of the displacement vortexes SE.

This configuration makes deformation or displacement of the vortexes at the base section easier, thereby eliminating vibration leakage from the resonating arms at a position of the groove or slit; thus preventing vibration leakage from being transmitted to a joined portion such as a portion that connects the resonator to the package. Accordingly, increases in the CI value and unwanted modes are less likely to occur, and deterioration of temperature characteristics can be prevented.

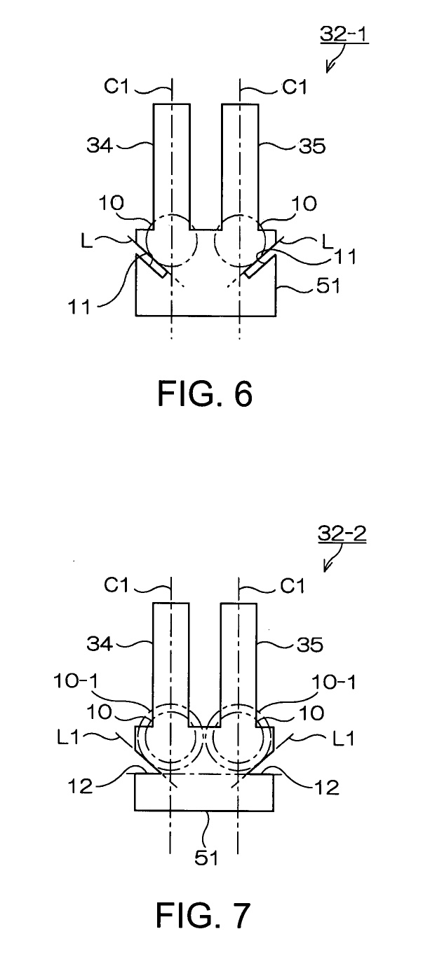

FIG. 6 to FIG. 10 show configurations of the piezoelectric resonator element, wherein long grooves or electrodes which are unnecessary for explanation are not illustrated for simplicity.

FIG. 6 shows a first configuration of a piezoelectric resonator element 32-1, which has a similar configuration as that shown in FIG. 3. The same reference numerals are given to elements that have already been explained herein to avoid redundant explanation, and explanation will be given mainly on the characteristic portions.

As has already been described referring to FIG. 5, a pair of displacement vortexes, which may also be referred to as centers of displacement of the flexural vibration of the resonating arms 34, 35, exist on the virtual center lines Cl of the width dimension of the resonating arms 34, 35. In FIG. 6, since the peripheries of the displacement vortexes are substantially circular, circles 10 corresponding to the displacement vortexes are shown.

Tangent lines L to the circles 10 of the displacement vortexes are provided. Slits 11 are formed at the base section 51 along the tangent lines L; that is, along a direction diagonally intersecting with a direction in which the resonating arms 34, 35 extend. That is, the slits 11 are long penetrating grooves which penetrate the material, or they may be bottomed grooves. The slits 11 that penetrate the material may considerably decrease rigidity of the base section 51 at the portion where the slits 11 are formed. If the slits 11 are bottomed grooves, their rigidity may be slightly higher than slits 11 that do not penetrate the material.

Accordingly, provision of such slits 11 enables making deformation or displacement of the displacement vortexes of the base section 51 easier. As a result, vibration leakage from the resonating arms 34, 35 can be eliminated at the positions of the slits 11 of the base section 51, and thereby the vibration leakage may be prevented from being transmitted to a joined portion. Accordingly, increase in the Cl value and unwanted modes are less likely to occur, and deterioration of temperature characteristics can be prevented.

FIG. 7 shows a second configuration of a piezoelectric resonator 32-2, which has a similar configuration as the other configurations. The same reference numerals are given to elements that have already been explained herein to avoid redundant explanation, and explanation will be given mainly on the characteristic portions.

As shown in FIG. 7, circles 10 correspond to a pair of displacement vortexes, which may also be referred to as centers of displacement of the flexural vibration, are shown on virtual center lines CI of the width dimension of resonating arms 34, 35, and in the vicinity of the bottom of the resonating arms 34, 35 of the base section 51.

In FIG. 7, circles 10-1 that may have a larger diameter than, and are concentric, with the circles 10 of the displacement vortexes are further provided outside of the circles 10 of the displacement vortexes.

Further, in the second embodiment, tangent lines L1 to the circles 10-1 are provided. Substantially rectangular slits 12 along the tangent lines L1 (i.e., in a direction diagonally intersecting with a direction in which the resonating arms 34, 35 extend) and by a direction perpendicular thereto are formed at the base section 51.

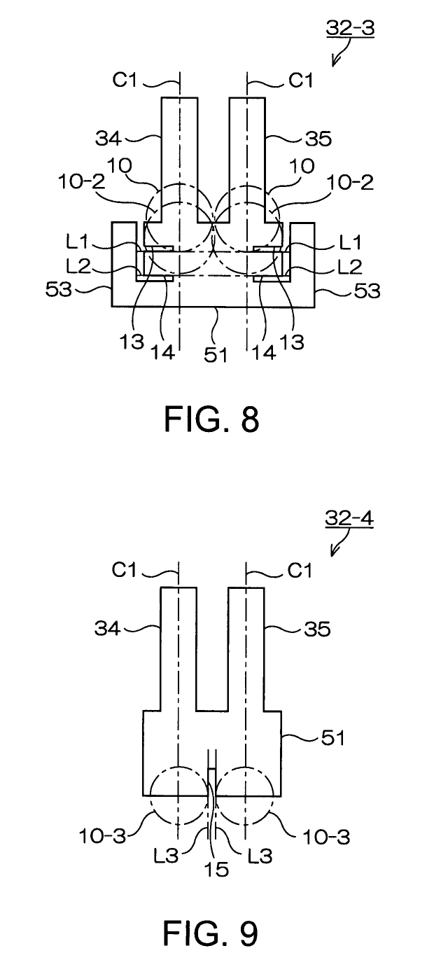

FIG. 8 shows a third configuration of the piezoelectric resonator element 32-3, where the base section 51 projects laterally in the width direction and has a pair of frame sections 53 that extend parallel to each other in the same direction as resonating arms 34, 35. The same reference numerals are given to elements that have already been explained herein to avoid redundant explanation, and explanation will be given mainly on the characteristic portions.

As shown in FIG. 8, circles 10 corresponding to a pair of the displacement vortexes, which may also be referred to as centers of flexural vibration, are shown on virtual center lines CI of the width dimension of the resonating arms 34, 35 and in the vicinity of the bottom of the resonating arms 34, 35 of the base section 51.

In FIG. 8, circles 10-2 having a larger diameter than the circles 10 of the displacement vortexes are provided at positions that have been moved in parallel from positions of the circles 10 of the displacement vortexes in a direction opposite to the resonating arms 34, 35.

In addition, tangent lines L1. and L2 to the circles 10 and 10-2 of the displacement vortexes are provided. Slits 13 and 14 may be formed at the base section 51 along the tangent lines L1 and L2 (i.e., in a direction perpendicular to direction in which the resonating arms 34, 35 extend.)

The third configuration achieves substantially the same advantageous effects as the first configuration. Further, since there are more slits, the advantageous effect thereof can be further increased.

FIG. 9 shows a fourth configuration of a piezoelectric resonator element 32-4, which has substantially the same configuration as the first configuration. The same reference numerals are given to elements that have already been explained herein to avoid redundant explanation, and explanation will be given mainly on the characteristic portions.

It has been described referring to FIG. 6, that the circles 10 corresponding to a pair of the displacement vortexes, which may also be referred to as centers of flexural vibration, are assumed to be provided on the virtual center lines CI of the width dimension of the resonating arms 34, 35, and in the vicinity of the bottom of the resonating arms 34, 35 of the base section 51.

In FIG. 9, circles 10-3 having the same diameter as the circles 10 of the displacement vortexes are provided at positions at the end portion of the base section 51 that move in parallel from the positions of the circles 10 of the displacement vortexes in the direction opposite to the distal ends of the resonating arms, 34, 35.

Further, in the fourth configuration, tangent lines L3 to the circles 10-3 of the circles are provided at positions between the circles 10-3. A slit 15 is formed along the tangent lines L3 in the same direction as the direction in which the resonating arms 34, 35 extend.

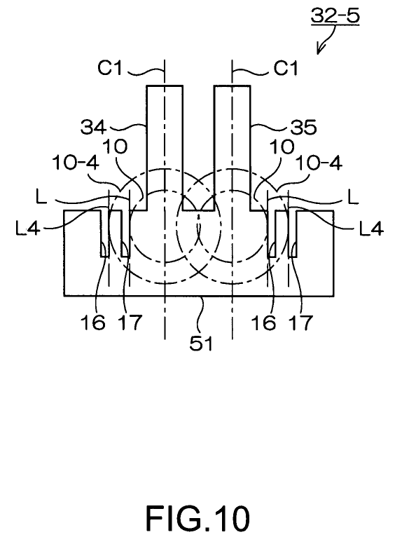

FIG. 10 shows a fifth configuration of a piezoelectric resonator element 32-5 where the base section 51 projects laterally in the width direction. The same reference numerals are given to elements that have already been explained herein to avoid redundant explanation, and explanation will be given mainly on the characteristic portions.

As shown in FIG. 10, circles 10 of the displacement vortexes, which should also be referred to as centers of flexural vibration, are shown on virtual center lines Cl of the width dimension of the resonating arms 34, 35, and in the vicinity of the bottom of the resonating arms 34, 35 of the base section 51.

In the fifth configuration, circles 10-4 having a larger diameter than and concentric with the circles 10 of the displacement vortexes are further provided outside of the circles 10 of the displacement vortexes.

In the fifth configuration, tangent lines L to the circles 10 at positions outside of the circles 10 of the displacement vortexes are provided. Slits 16 are formed at the base section 51 along the tangent lines Lin a direction parallel to the direction in which the resonating arms 34, 35 extend.

In addition, tangent lines L4 to the circles 10-4 are provided at positions outside of the circles 10-4 as described above. Slits 17 are formed at base section 51 along the tangent lines L along a direction parallel to the direction in which the resonating arms 34, 35 extend.

The fifth configuration achieves substantially the same operational effects as the first configuration. Further, since there are more slits, the operational effects thereof can be further increased.

The present teachings are not limited to the configurations described above. Each of the configurations may be combined with one another as appropriate, or may be combined with other configuration which is not shown.

In addition, the present teachings may be applied to any piezoelectric resonator element and piezoelectric device using the same as long as a piezoelectric resonator element is housed in a package, regardless whether a quartz crystal resonator, quartz crystal resonator, gyro, angle sensor, acceleration sensor, and the like are employed.

Further, although a box-shaped package using ceramic is employed in the configurations described above, the package should not be limited thereto. The present teachings may be applied to any device with any package or case as long as a piezoelectric resonator element is housed in a container that is equivalent to a package such as a cylinder-shaped metal case.

1. A piezoelectric resonator element comprising:
a base section made of a piezoelectric material; and
at least a pair of resonating arms integrally formed with the base section, the resonating arms extending from the base section parallel to each other,
wherein, a slit is provided along a line tangent to a periphery of a displacement vortex, said displacement vortex formed at a base end of each of the resonating arms that is connected to the base section and on a virtual center line that passes through a center width of each resonating arm, said displacement vortex being substantially circular and generated by flexural vibration of the resonating arms.

2. The piezoelectric resonator element according to claim 1, wherein a second slit is provided along another line tangent to a circle concentric with said periphery of said displacement vortex.

3. The piezoelectric resonator element according to claim 1, wherein a second slit is provided along a line tangent to a circle which is created by moving a circle corresponding to said periphery of said displacement vortex in a direction in which said virtual center line extends.

4. The piezoelectric resonator element according to claim 1, wherein said slit extends in a direction that diagonally intersects a direction in which said resonating arms extend.

5. The piezoelectric resonator element according to claim 1, wherein said slit is perpendicular to a direction in which said resonating arms extend.

6. The piezoelectric resonator element according to claim 1, wherein said slit is parallel to a direction in which said resonating arms extend.

7. The piezoelectric resonator element according to claim 1, wherein said slit is curved along said line tangent said periphery of said displacement vortex.

8. The piezoelectric resonator element according to claim 1, wherein each of said resonating arms includes a groove that extends in a longitudinal direction, and an excitation electrode formed in said groove.

9. A piezoelectric device housing a piezoelectric resonator element in a housing container, wherein the piezoelectric resonator element comprises:
a base section made of a piezoelectric material; and
at least a pair of resonating arms integral with the base section, the resonating arms extending parallel to each other from the base section,
wherein a slit is provided along a line tangent to a circular displacement vortex, said displacement vortex generated by flexural vibration of the pair of resonating arms and located at a base end of each of the resonating arms connected to the base section and on a virtual center line that passes through a center width of each resonating arm.

10. The piezoelectric resonator of claim 2, wherein said second slit is provided in place of said slit provided along said line tangent to said periphery of said displacement vortex.

11. The piezoelectric resonator element according to claim 3, wherein said second slit is provided along a line tangent to a circle concentric with said circle created by moving said circle corresponding to said periphery of said displacement vortex in a direction in which said virtual center line extends.

12. The piezoelectric resonator element according to claim 3, wherein said second slit is provided in place of said slit provided along said line tangent to said periphery of said displacement vortex.

13. The piezoelectric resonator element according to claim 11, wherein said second slit is provided in place of said slit provided along said line tangent to said periphery of said displacement vortex.

14. The piezoelectric resonator element according to claim 11, wherein said slit is curved along said line tangent to said circle concentric with said displacement vortex.

15. A piezoelectric resonator element comprising:
a base section;
a pair of resonating arms extending parallel to each other from said base section, each of said resonating arms including a proximate end connected to said base section and a distal end disposed away from said base section; and
at least one slit formed in said base section at said proximate end of said resonating arms,
wherein said slit is along a line tangent to a displacement vortex formed by flexural vibration of said resonating arms where said proximate end of said resonating arms connects to said base section.

16. The piezoelectric resonator element of claim 15, wherein said slit is acutely angled relative to a direction in which said resonating arms extend.

17. The piezoelectric resonator element of claim 15, wherein said slit is perpendicular to a direction in which said resonating arms extend.

18. The piezoelectric resonator element of claim 15, wherein said slit is parallel to a direction in which said resonating arms extend.

19. The piezoelectric resonator element of claim 15, wherein said slit completely penetrates said base section.

20. The piezoelectric resonator element of claim 15, further comprising another slit, said another slit formed along a line tangent to a circle disposed away from a center of said displacement vortex.

21. The piezoelectric resonator element of claim 20, wherein said circle is concentric with said center of said displacement vortex.

22. The piezoelectric resonator element of claim 20, wherein said circle is offset from said center of said displacement vortex.

23. A piezoelectric device comprising:
the piezoelectric resonator element of claim 15; and
a case that houses the piezoelectric element.

24. The piezoelectric resonator element of claim 15, wherein said resonating arms include an extraction electrode and an excitation electrode.

25. A piezoelectric resonator element comprising:
a base;
a pair of resonating arms extending parallel to each other outward from said base, said resonating arms including a proximate end attached to said base and a distal end away from said base; and
a pair of slits formed in said base near said proximate ends of said resonating arms, each slit formed along a line tangent to a circular displacement vortex formed by flexural vibration of said resonating arms in said base.
